(19) United States
(12) Patent Application Publication
(10) Pub. No.: US 2026/0068589 A1
(43) Pub. Date: Mar. 5, 2026

(54) ROTOR ASSEMBLY WITH DISPLACEABLE AXIAL SENSORS

(71) Applicant: SKF CANADA LIMITED, Scarborough (CA)

(72) Inventors: Daren Paul TREMAINE, Silverton (CA); Timothy Andrew HARRIS, Calgary (CA); Tracy Kathryn STREM, Calgary (CA)

(21) Appl. No.: 18/824,068

(22) Filed: Sep. 4, 2024

(51) Int. Cl. H01L 21/677; B65G 65/00; H01L 21/67

(52) U.S. Cl. CPC H01L 21/67778; B65G 65/00

(57) ABSTRACT

A rotor assembly includes a rotor disposable around a central member, connectable with a holder and having upper and lower axial ends. A stator assembly includes a housing having a central bore, the rotor and central member being disposed within the bore, and electromagnetic coil assemblies disposed within the housing, spaced around the axis and configured to exert magnetic torque on the rotor such that the rotor angularly displaces about the central axis. One or more actuators are configured to linearly displace the stator assembly and the rotor along the central axis relative to the central member. A sensor assembly is connected with the stator housing and includes an axial position sensor spaced axially from the lower axial end of the rotor and configured to sense the position of the rotor along the central axis, the axial position sensor being displaceable axially when the actuator displaces the stator housing.

### BACKGROUND OF THE INVENTION

The present invention relates to sensors, and more particularly to position sensors used to detect rotating components of electromagnetic machinery.

Position sensors are well known and used in a wide variety of applications. One particular usage of position sensors is to detect the axial position of a levitated rotor in an electromagnetic machine, such as a semiconductor wafer processing machine. In such an application, the sensor detects the axial position of the rotor and sends position signals to a controller which operates the levitation actuators that maintain the rotor at a particular axial position with respect to a stator assembly. Precise control of the levitation actuators is critical as the rotor cannot be allowed to vertically “drop” away from the actuators or to alternatively be pulled into contact with the actuators and potentially damage the actuators and/or the rotor.

In order to facilitate the loading and unloading of a part, such as a semiconductor wafer, onto or off of a holder that is rotated by the rotor, the stator assembly and rotor may be axially displaceable between upper and lower positions. Specifically, the stator assembly and rotor may be displaced axially downwardly to a loading/unloading position in which the part is at least partly supported on a fixed central member disposed within the rotor. Once an unprocessed part has been loaded onto the holder, the stator assembly and rotor are then displaced axially upwardly to a processing position in which the part is spaced above the central member and free to be angularly displaced about a central axis. Due to such axial displacement, an axial position sensor is typically mounted on the stator assembly so as to be spaced radially outwardly from the rotor and functions to detect a circumferential surface or end of the rotor. As a result, the detected axial position of the rotor may not be as accurate as desired.

### SUMMARY OF THE INVENTION

In one aspect, the present invention is a rotor assembly for angularly displacing a holder about a central axis, the holder retaining a part vertically above a static central member during a manufacturing process. The rotor assembly comprises an annular rotor disposable around at least a portion of the central member, connectable with the holder and having opposing upper and lower axial ends. A stator assembly includes a housing having a central bore, the rotor and the central member being disposed within the central bore, and a plurality of electromagnetic coil assemblies disposed within the housing, spaced circumferentially about the central axis and configured to exert magnetic torque on the rotor such that the rotor angularly displaces about the central axis. At least one actuator is configured to linearly displace the stator assembly and the rotor along the central axis relative to the central member. Further, a sensor assembly is connected with the housing of the stator assembly and includes an axial position sensor spaced axially from the lower axial end of the rotor and configured to sense the position of the rotor along the central axis. The axial position sensor is displaceable axially when the actuator displaces the housing of the stator assembly.

In another aspect, the present invention is a machine for processing at least one part, the machine comprising a holder configured to retain the at least one part and a static central member having an upper end, the part being at least partially disposable upon the upper end of the central member. An annular rotor is disposed around at least a portion of the central member, connected with the holder and having opposing upper and lower axial ends. A stator assembly includes a housing having a central bore, the rotor being disposed within the central bore, and a plurality of electromagnetic coil assemblies disposed within the housing, spaced circumferentially about the central axis and configured to exert magnetic torque on the rotor such that the rotor angularly displaces about the central axis to rotate the holder and the part about the axis. An actuator is configured to linearly displace the stator assembly and the rotor along the central axis relative to the central member so as to displace the holder and the part above the upper end of the central member and to alternatively place the part upon the upper end of the central member. Further, a sensor assembly is connected with the housing of the stator assembly and includes an axial position sensor spaced axially from the lower axial end of the rotor and is configured to sense the position of the rotor along the central axis. The axial position sensor is displaceable axially when the actuator displaces the housing of the stator assembly.

### BRIEF DESCRIPTION OF THE SEVERAL VIEWS OF THE DRAWINGS

The foregoing summary, as well as the detailed description of the preferred embodiments of the present invention, will be better understood when read in conjunction with the appended drawings. For the purpose of illustrating the invention, there is shown in the drawings, which are diagrammatic, embodiments that are presently preferred. It should be understood, however, that the present invention is not limited to the precise arrangements and instrumentalities shown. In the drawings:

FIG. 1 is a broken-away, axial cross-sectional view in perspective of an electromagnetic processing machine having a rotor assembly in accordance with the present invention;

FIG. 2 is an axial cross-sectional view of the machine of FIG. 1;

FIG. 3 is a view through line 3-3 of FIG. 2;

FIG. 4 is a broken-away, axial cross-sectional view of the rotor assembly of the present invention, shown located at a load/unload position with respect to a central member;

FIG. 5 is an enlarged view of a portion of FIG. 4;

FIG. 6 is a broken-away, axial cross-sectional view of the rotor assembly of the present invention, shown located at a processing position with respect to the central member;

FIG. 7 is an enlarged view of a portion of FIG. 6;

FIG. 8 is a more enlarged view of a portion of FIG. 5; and

FIG. 9 is a more enlarged view of a portion of FIG. 7.

### DETAILED DESCRIPTION OF THE INVENTION

Certain terminology is used in the following description for convenience only and is not limiting. The words “lower”, “upper”, “upward”, “down” and “downward” designate directions in the drawings to which reference is made. The words “inner”, “inwardly” and “outer”, “outwardly” refer to directions toward and away from, respectively, a designated centerline or a geometric center of an element being described, the particular meaning being readily apparent from the context of the description. Further, as used herein, the words “connected” and “coupled” are each intended to include direct connections between two members without any other members interposed therebetween and indirect connections between members in which one or more other members are interposed therebetween. The terminology includes the words specifically mentioned above, derivatives thereof, and words of similar import.

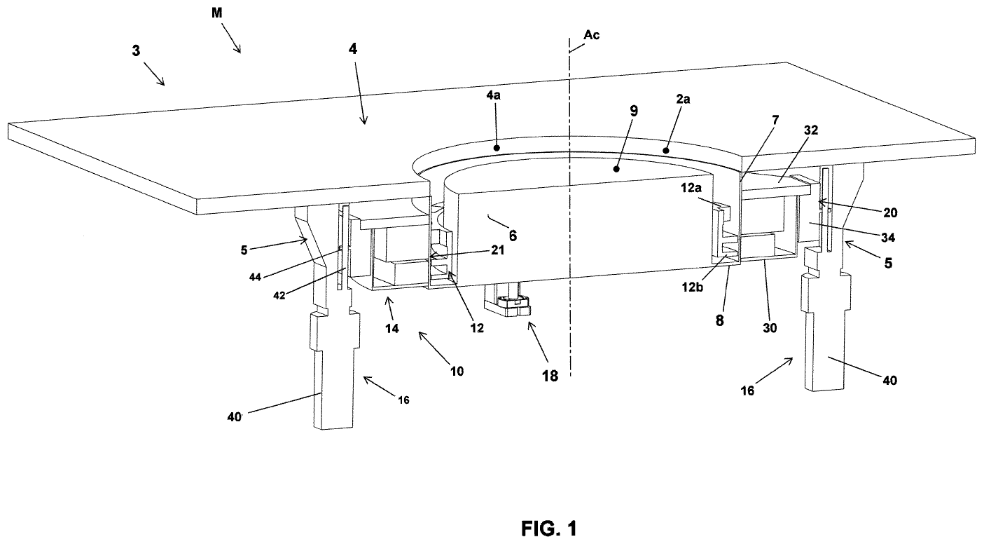

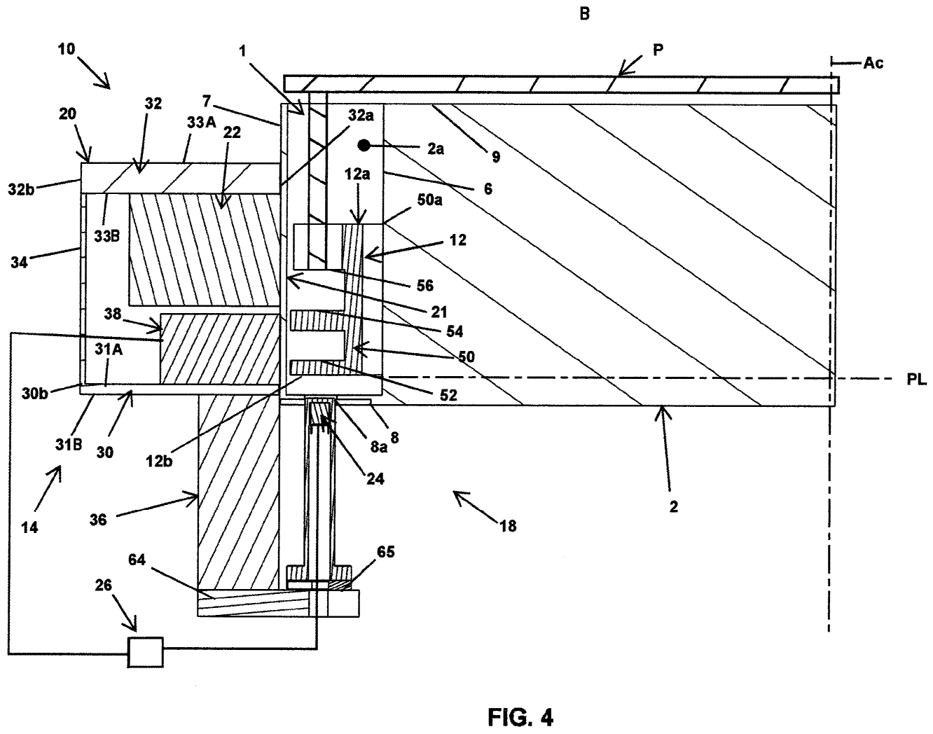

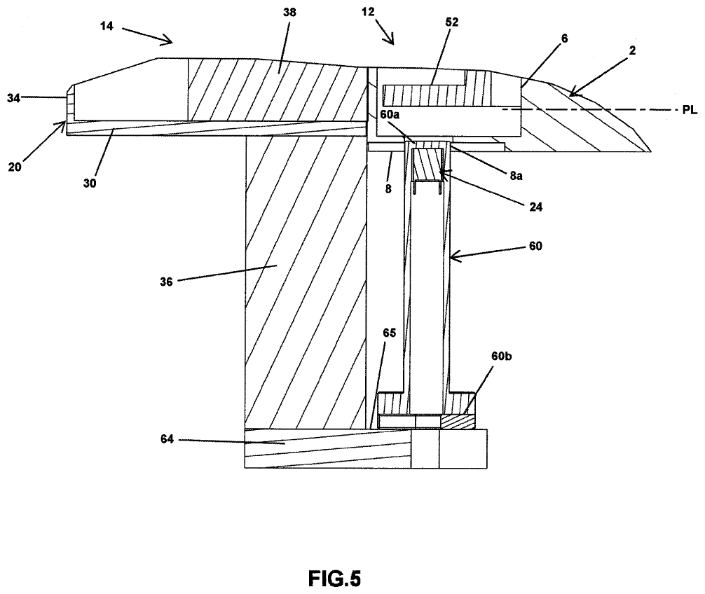

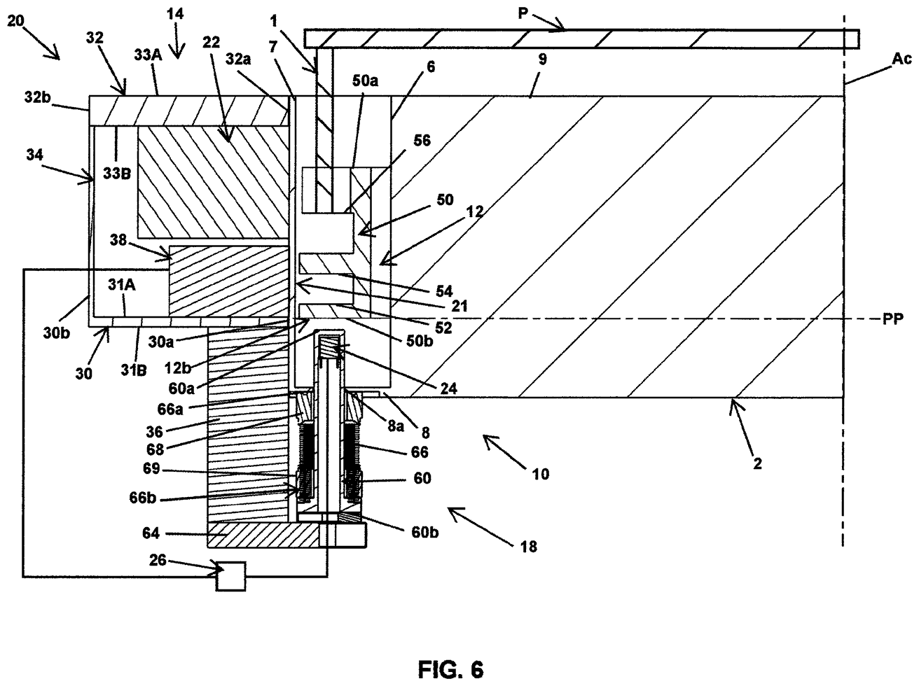

Referring now to the drawings in detail, wherein like numbers are used to indicate like elements throughout, there is shown in FIGS. 1-9 a rotor assembly 10 for angularly displacing a holder 1 about a central axis A_{C}, the holder 1 retaining a part P (FIGS. 4 and 6) vertically above a static central member 2 during a manufacturing process, the rotor assembly 10, the holder 1 and the static member 2 each being incorporated into a processing machine M. Preferably, the part P is a semiconductor wafer and the processing machine M is a machine used to fabricate or perform one or more processes on a semiconductor wafer, such as for example, a thermal process or a chemical process, but may be any other part or machine which is processed during angular rotation. Basically, the rotor assembly 10 comprises an annular rotor 12, a stator assembly 14 for rotating the rotor 12, at least one lift actuator 16 for axially displacing both the rotor 12 and the stator 14 relative to the central member 2 and a sensor assembly 18 axially displaceable with the rotor 12 and the stator assembly 14.

Specifically, the annular rotor 12 is disposable around at least a portion the central member 2, is connectable with the holder 1 and has opposing upper and lower axial ends 12a, 12b. The stator assembly 14 includes a housing 20 having a central bore 21, the rotor 12 and central member 2 being disposed within the central bore 21, and a plurality of electromagnetic coil assemblies 22 disposed within the housing 20. The electromagnetic coil assemblies 22, or motor actuators 22, are spaced circumferentially about the central axis A_{C} and are configured to exert magnetic torque on the rotor 12 such that the rotor 12 angularly displaces about the central axis A_{C}.

Further, the one or more lift actuators 16 are configured to linearly displace the stator assembly 14 and the rotor 12 along the central axis A_{C} relative to the central member 2.

Specifically, the actuators 16 displace the stator assembly 14 and the rotor 12 between a lower, load/unload position PL, as indicated in FIGS. 4, 5 and 8, in which the part P is at least partially supported by the central member 2 and is placed on and/or within the holder 1, and alternatively removed from the holder 1, and an upper, processing position PP, indicated in FIGS. 6, 7 and 9, in which the part P is supported solely by the holder 1 so as to be spaced above the central member 2 and is angularly displaced by the rotor 12 during processing. The sensor assembly 18 is connected with the housing 20 of the stator assembly 14 and includes an axial position sensor 24 spaced axially from the lower axial end 12b of the rotor 12. The axial position sensor 24 is configured to sense the position of the rotor 12 along the central axis A_{C} and is displaceable axially when the actuator 16 displaces the housing 20 of the stator assembly 12. Thereby, the sensor 24 is capable of accurately determining the axial position of the rotor 12 relative to the stator assembly 14, which is preferably sent to a controller 26 (FIGS. 4 and 6) which operates one or more levitation actuator(s) 38 that retain the rotor 12 at a desired axial position, as described below.

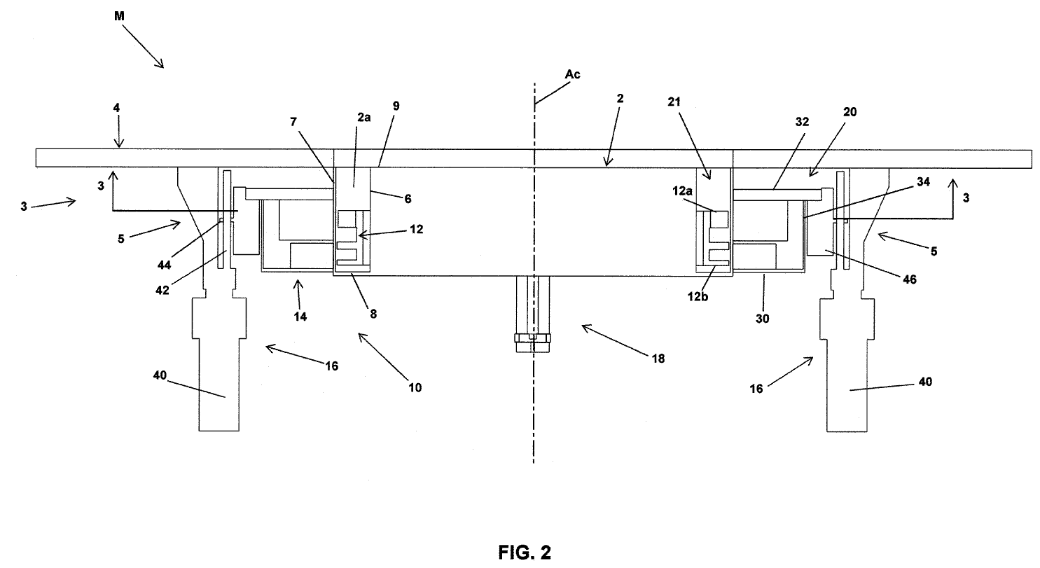

Referring first to FIGS. 1 and 2, the processing machine M preferably further includes mainframe 3 formed of a table 4 and a plurality of support posts 5, the table 4 having a central bore 4a within which the central member 2 is partially disposed. The central member 2 preferably includes an inner cylindrical body 6, an outer cylindrical sidewall 7 and an annular base wall 8 extending between and connecting the inner body 6 with the outer sidewall 7. As such, an annular bore 2a is defined between the inner body 6 and the outer sidewall 7, the rotor 12 being disposed within the bore 2a. Further, the outer sidewall 7 is connected to the mainframe table 4 and the inner sidewall 6 has a radial support surface 9 upon which the part P may be placed and at least partially supported when the holder 1 is in load/unload position PL, as described below. Also, the base wall 8 has an opening 8a for receiving a portion of a sensor housing 60, as described below.

Referring to FIGS. 2, 4 and 6, the stator housing 20 is preferably generally annular and includes an annular lower baseplate 30, an annular upper baseplate 32 and a cylindrical outer sidewall 34. The lower baseplate 30 has an inner radial end 30a partially defining the central bore 21, an outer radial end 30b and upper and lower axial surfaces 31A, 31B. The upper baseplate 32 is spaced axially above the lower baseplate 30 and has an inner radial end 32a partially defining the central bore 21, an outer radial end 32b and upper and lower axial surfaces 33A, 33B. Preferably, the plurality of electromagnetic coil assemblies or “motor actuators” 22 are mounted to the lower axial surface 33B of the upper baseplate 32. Further, the outer sidewall 34 extends circumferentially around the lower and upper baseplates 30, 32 and is connected with the outer radial end 30b, 32b of each baseplate 30, 32.

Preferably, the stator assembly 14 further includes a mounting bracket 36 attached to the lower axial surface 31B of the lower baseplate 30 and which connects the sensor assembly 18 to the stator assembly 14. Also, stator assembly 14 preferably further includes at least one and preferably a plurality of levitation actuators 38 and at least one and preferably a plurality of radial actuators (none shown). The levitation actuators 38 are configured to exert magnetic force on the rotor 12 so as to retain a vertical position of the rotor 12 along the central axis A_{C}, and thereby magnetically couples the rotor 12 with the stator assembly 14 such that the rotor 12 displaces along the central axis A_{C} when the lift actuators 16 displace the stator assembly 12 along the central axis A_{C}, as discussed in further detail below. As mentioned above, the axial position information from the axial sensor 24 is transmitted to the controller 26, which operates the levitation actuators 38 to maintain a desired axial position of the rotor 12 with respect to the stator assembly 14. Further, the controller 26 or another controller (not shown) receives radial position information from radial sensors (none shown) and operates the radial actuators to maintain the rotor 12 centered on the central axis A_{C}.

As best shown in FIGS. 1 and 2, each lift actuator 16 is preferably mounted to a separate one of the support posts 5 of the mainframe 3 and is formed as a screw jack including an electric drive motor 40, a power screw 42 and a nut block 44 disposed upon the screw 42 and connected with the stator housing 18. Preferably, an adapter block 46 connects the nut block 44 with the outer sidewall 34 of the stator assembly housing 20. With this arrangement, rotation of the power screw 42 in one angular direction displaces the nut block 44, and thereby the stator assembly 14 and the rotor 12, upwardly along the central axis A_{C} toward the processing position PP (FIG. 6) and alternatively, rotation of the power screw 42 in the opposing angular direction displaces the nut block 44, the stator assembly 14 and the rotor 12 downwardly along the central axis A_{C} toward the load/unload position PL (FIG. 4). Although a plurality of lift actuators 16 formed as screw jacks is presently preferred, the rotor assembly 10 may include only a single jack screw lift actuator 16, in combination with a sliding support member(s), or one or more actuators 16 formed in another appropriate manner, such as for example, hydraulic cylinders, etc.

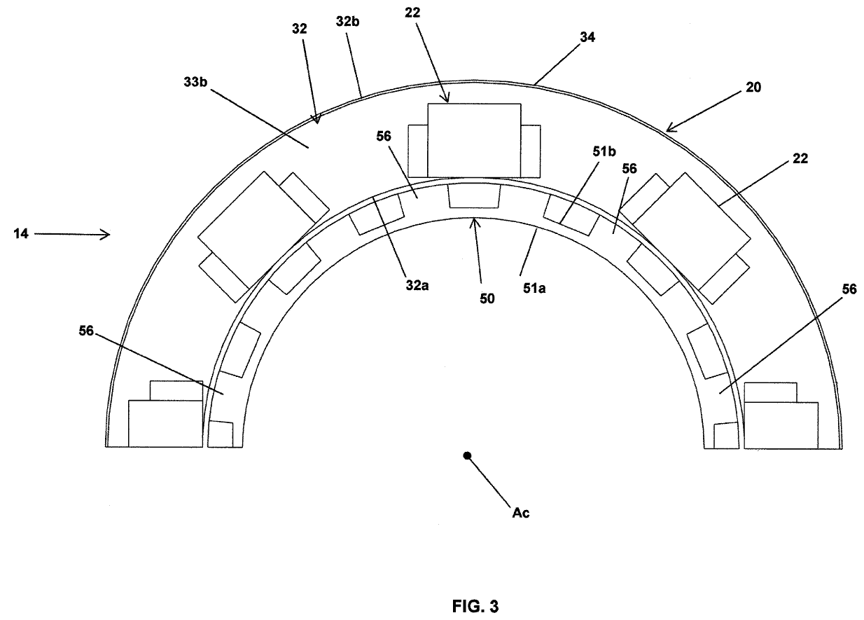

Referring to FIGS. 3, 4 and 6, the rotor 12 preferably includes a cylindrical sidewall 50, a lower flange 52, a central flange 54 and a plurality of rotor teeth 56. The sidewall 50 includes upper and lower axial ends 50a, 50b, an inner circumferential surface 51A and an outer circumferential surface 51B. The lower flange 52 extends radially outwardly from the outer circumferential surface 51B at the lower axial end 50b of the sidewall 50b, the axial position sensor 24 being spaced axially apart from and configured to sense the lower flange 52 as discussed below. The central flange 54 extends radially outwardly from the outer circumferential surface 51B of the sidewall 50 and is disposed axially between the upper and lower axial ends 50a, 50b of the sidewall 50. Each levitation actuator 38 is magnetically engaged with the central flange 54 so as to magnetically couple the rotor 12 with the stator assembly 14, and thereby retain the rotor 12 at a specific position on the central axis A_{C}, for example at the load/unload position PL or the processing position PP.

Further, the plurality of teeth 56 extend radially outwardly from the sidewall 50 adjacent to the sidewall upper end 50a, and are thus spaced axially above the lower radial flange 52. Each one of the plurality of electromagnetic coil assemblies 22 are configured to exert magnetic torque on one or more of the teeth 56 when electric current flows through the coil assemblies 22, so as to angularly displace the rotor 12 about the central axis A_{C} and thereby rotate the holder 1 and the part P during processing.

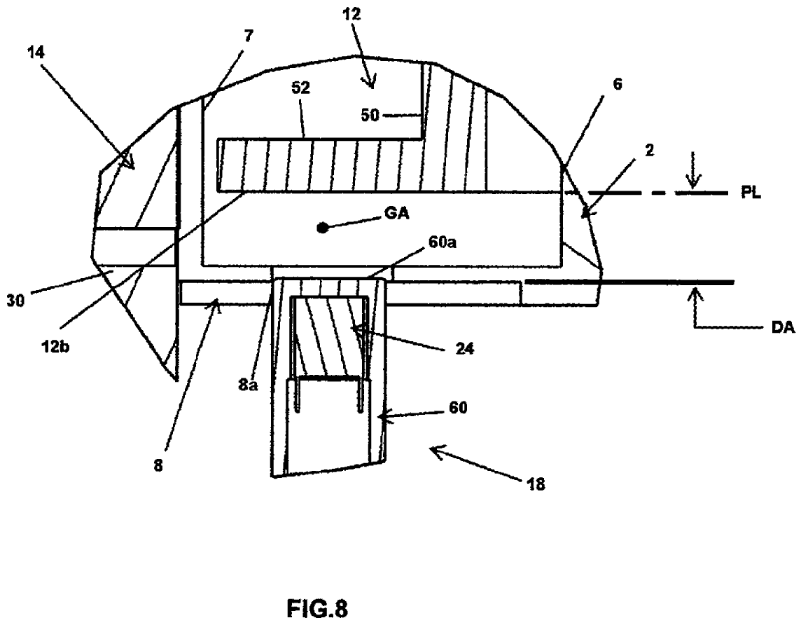

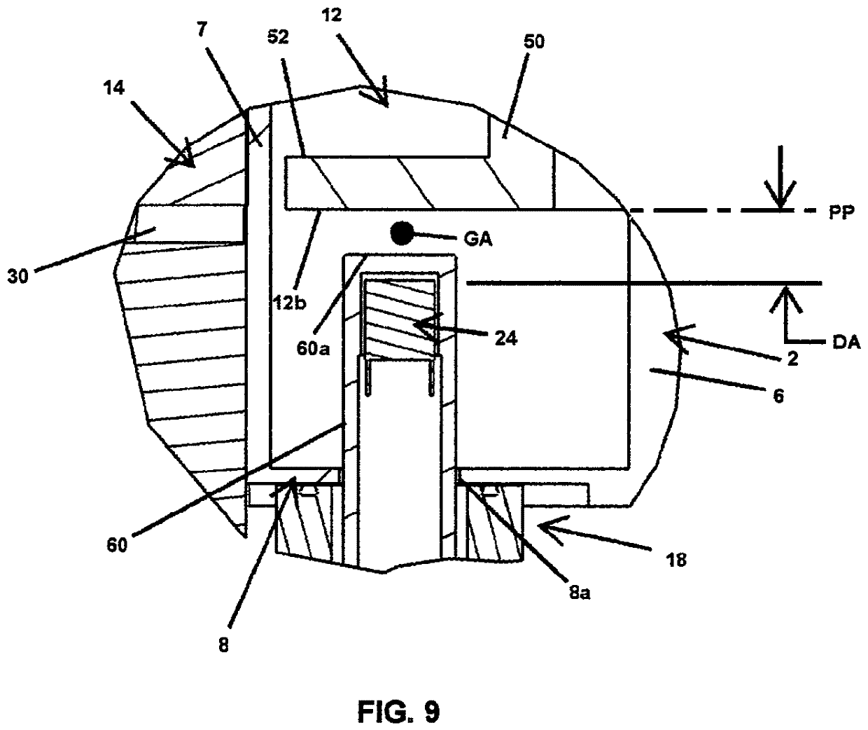

Referring now to FIGS. 4-7, the sensor assembly 18 includes a sensor housing 60 connected with the housing 20 of the stator assembly 14. Specifically, the sensor housing 60 is disposed on the mounting bracket 36 attached to extending vertically downwardly from the lower axial surface 31B of the lower baseplate 30, as discussed above. As such, the housing 60, and thereby the axial position sensor 24, is displaceable along the central axis A_{C} when the lift actuators 16 move the stator assembly 20 and the coupled rotor 12 to maintain a desired axial gap GA (FIGS. 8 and 9) between the sensor 24 and the rotor lower flange 52.

The sensor housing 60 is preferably formed as an elongated tube having an upper axial end 60a and a lower axial end 60b. The axial position sensor 24 is mounted adjacent to the upper end 60a of the sensor housing 60 and the lower axial end 60a is attached to an upper surface 65 of a lower plate 64 of the mounting bracket 36. The sensor housing 60 extends through the opening 8a in the base wall 8 of the central member 2 such that the sensor 24 is positioned spaced axially from the rotor 12 by the annular gap GA. When the stator assembly 14 is displaced by the lift actuators 16, the tubular housing 60 of the sensor assembly 18 displaces through the opening 8a.

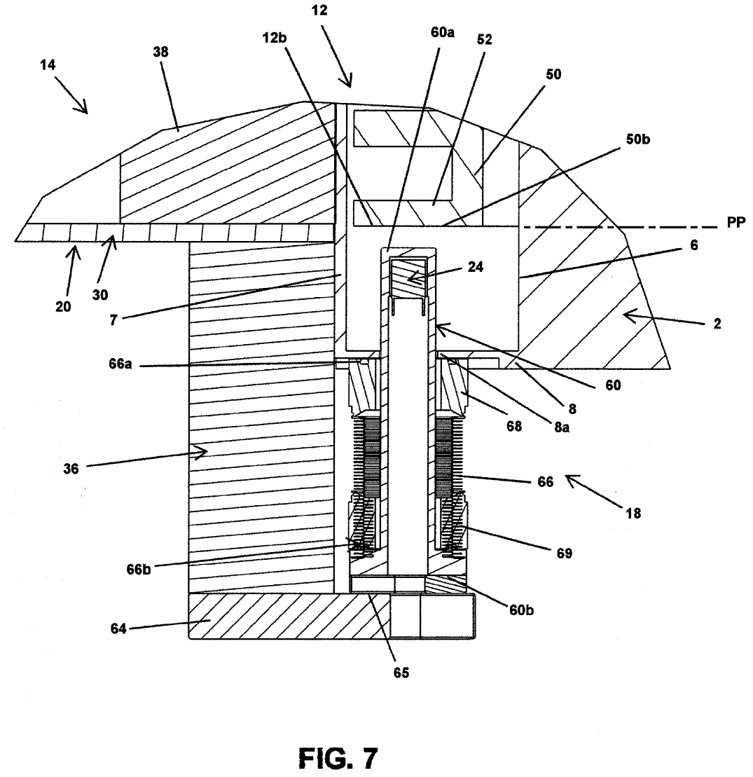

Referring particularly to FIGS. 6 and 7, in order to ensure sterile operating conditions of the machine M, the sensor assembly 18 preferably further includes a collapsible enclosure 66 disposed about at least a portion of the sensor housing 60. The enclosure 66 has an upper end 66a attachable to the central member 2, specifically to the base wall 8, and a lower end 66b attached to the lower end 60b of the sensor housing 60. The collapsible enclosure 66 is preferably formed as a metallic bellows and is attached to the central member base wall 8 by an upper collar 68 and to the sensor housing lower end 60b by a lower collar 69.

Referring now to FIGS. 8 and 9, the axial position sensor 24 is preferably a proximity sensor configured to detect an axial distance DA between the sensor 24 and the lower axial end 12a of the rotor 12, more precisely between the lower flange 52 and the sensor 24, in order to maintain the desired axial gap GA. Specifically, the sensor 24 is electrically coupled with the controller 26, e.g., by wires or wireless transmission, and sends the detected axial distance DA to the controller 26 such that the controller 26 operates the levitation actuators 38 to maintain the rotor 12 at a desired axial position relative to the stator assembly 14. Although a proximity sensor is presently preferred, the axial position sensor 24 may be any other appropriate type of sensor capable of measuring the axial distance between the sensor 24 and the rotor 12. In any case, due to the axial position sensor 24 sensing an axial end 12b of the rotor 12, rather than a circumferential side of the rotor 12, the detected axial distance DA provides a very accurate measurement of the axial position of the rotor 12 along the central axis A_{C} and enables precise control of the levitation actuators 38.

Representative, non-limiting examples of the present invention were described above in detail with reference to the attached drawings. This detailed description is merely intended to teach a person of skill in the art further details for practicing preferred aspects of the present teachings and is not intended to limit the scope of the invention.

Moreover, combinations of features and steps disclosed in the above detailed description may not be necessary to practice the invention in the broadest sense, and are instead taught merely to particularly describe representative examples of the invention. Furthermore, various features of the above-described representative examples, as well as the various independent and dependent claims below, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter. The invention is not restricted to the above-described embodiments, and may be varied within the scope of the following claims.

We claim:

1. A rotor assembly for angularly displacing a holder about a central axis, the holder retaining a part vertically above a static central member during a manufacturing process, the rotor assembly comprising:
an annular rotor disposable around at least a portion of the central member, connectable with the holder and having opposing upper and lower axial ends;
a stator assembly including a housing having a central bore, the rotor being disposed within the central bore, and a plurality of electromagnetic coil assemblies disposed within the housing, spaced circumferentially about the central axis and configured to exert magnetic torque on the rotor such that the rotor angularly displaces about the central axis;
at least one actuator configured to linearly displace the stator assembly and the rotor along the central axis relative to the central member; and
a sensor assembly connected with the housing of the stator assembly and including an axial position sensor spaced axially from the lower axial end of the rotor and configured to sense the position of the rotor along the central axis, the axial position sensor being displaceable axially when the actuator displaces the housing of the stator assembly.

2. The rotor assembly as recited in claim 1, wherein the axial position sensor is a proximity sensor configured to detect an axial distance between the sensor and the lower axial end of the rotor.

3. The rotor assembly as recited in claim 1, wherein the sensor assembly includes a sensor housing connected with the housing of the stator assembly and having an upper axial end and a lower axial end, the axial position sensor being mounted adjacent to the upper end of the sensor housing.

4. The rotor assembly as recited in claim 3, wherein the sensor housing extends through an opening in the central member and the sensor assembly further includes a collapsible enclosure disposed about at least a portion of the sensor housing and having an upper end attachable to the central member and a lower end attached to a lower end of the sensor housing.

5. The rotor assembly as recited in claim 3, wherein the housing of the stator assembly includes an annular lower baseplate, the lower baseplate having an inner radial end partially defining the central bore, an upper axial surface and a lower axial surface, and a bracket attached to the lower axial surface of the baseplate, the sensor housing being attached to the bracket.

6. The rotor assembly as recited in claim 5, wherein the housing of the stator assembly further includes an annular upper baseplate spaced axially above the lower baseplate and having an inner radial end partially defining the central bore, an upper axial surface and a lower axial surface, the plurality of electromagnetic coil assemblies being mounted to the lower axial surface of the upper baseplate.

7. The rotor assembly as recited in claim 1, wherein the stator assembly further includes at least one levitation actuator configured to exert magnetic force on the rotor so as to retain a vertical position of the rotor along the central axis.

8. The rotor assembly as recited in claim 7, wherein the at least one levitation actuator magnetically couples the rotor with the stator assembly such that the rotor displaces along the central axis when the actuator displaces the stator assembly along the central axis.

9. The rotor assembly as recited in claim 8, wherein the rotor includes a cylindrical sidewall, the sidewall having an upper axial end and a lower axial end, a lower flange extending radially outwardly from the lower axial end of the sidewall, the axial position sensor being spaced axially apart from and configured to sense the lower flange, and a central flange extending radially outwardly from the sidewall and disposed axially between the upper and lower axial ends of the sidewall, the at least one levitation actuator being magnetically engaged with the central flange.

10. The rotor assembly as recited in claim 1, wherein the rotor includes a cylindrical sidewall, the sidewall having an upper axial end and a lower axial end, a radial flange extending radially outwardly from the lower axial end and providing the rotor lower axial end, and a plurality of teeth extending radially outwardly from the sidewall and spaced axially above the lower radial flange, each one of the plurality of electromagnetic coil assemblies being configured to exert magnetic torque on one or more of the teeth so as to angularly displace the rotor about the central axis.

11. A machine for processing at least one part, the machine comprising:
a holder configured to retain the at least one part;
a static central member having an upper end, the part being at least partially disposable upon the upper end of the central member;
an annular rotor disposed around at least a portion the central member, connected with the holder and having opposing upper and lower axial ends;
a stator assembly including a housing having a central bore, the rotor being disposed within the central bore, and a plurality of electromagnetic coil assemblies disposed within the housing, spaced circumferentially about the central axis and configured to exert magnetic torque on the rotor such that the rotor angularly displaces about the central axis to rotate the holder and the part about the axis;
an actuator configured to linearly displace the stator assembly and the rotor along the central axis relative to the central member so as to displace the holder and the part above the upper end of the central member and to alternatively place the part upon the upper end of the central member; and
a sensor assembly connected with the housing of the stator assembly and including an axial position sensor spaced axially from the lower axial end of the rotor and configured to sense the position of the rotor along the central axis, the axial position sensor being displaceable axially when the actuator displaces the housing of the stator assembly.
